(19) United States
(12) Patent Application Publication
(10) Pub. No.: US 2019/0088451 A1
(43) Pub. Date: Mar. 21, 2019

(54) Integrated Thermal Management for Surface Treatment with Atmospheric Plasma

(71) Applicant: ONTOS Equipment Systems, Inc., Chester, NH (US)

(72) Inventors: Eric Frank Schulte, Santa Barbara, CA (US); Robert Emmett Hughlett, Waterbury, VT (US); Michael Dow Stead, Jeffersonville, VT (US); Joel Alfred Penelon, Monrovia, MD (US); Matthew Sheldon Phillips, Chester, NH (US); Daniel Nicholas Pascual, Wolcott, VT (US)

(73) Assignee: ONTOS Equipment Systems, Inc., Chester, NH (US)

(21) Appl. No.: 15/979,397

(22) Filed: May 14, 2018

Related U.S. Application Data
(60) Provisional application No. 62/505,797, filed on May 12, 2017.

(51) Int. Cl. H01J 37/32; H01L 23/00

(52) U.S. Cl. CPC H01J 37/3244; H01J 37/32825; H01J 37/32018; H01J 37/32834; H01L 2224/80895; H01L 24/80; H01J 2237/002; H01J 2237/335; H01L 2224/80013; H01J 37/32724

(57) ABSTRACT

Methods and systems for thermal management methods to control the rates of chemical reaction at the surface of a substrate being treated by atmospheric plasma. Integrated thermal management includes static heating and cooling of the plasma head and the substrate, as well as dynamic heating and cooling of the substrate surface, before and after the substrate passes the linear aperture of the atmospheric plasma head.

### CROSS-REFERENCE

Priority is claimed from U.S. provisional application 62/505,797, filed May 12, 2017, which is hereby incorporated by reference.

### BACKGROUND

The present application relates to processing of semiconductor devices, and more particularly to the thermal control of the chemical reactions occurring before, during, and after the modification of wafer and/or chip surfaces with atmospheric plasma. The principles disclosed here also apply to non-semiconductor processes where surface modification is being accomplished with atmospheric plasma.

Note that the points discussed below may reflect the hindsight gained from the disclosed inventions, and are not necessarily admitted to be prior art.

Atmospheric Plasma is currently used in the modification of surfaces such as in the semiconductor processing industry. U.S. Pat. No. 8,567,658, which is hereby incorporated by reference, is an example of modification of surfaces in the semiconductor processing industry with atmospheric plasma. The claims of that patent include controlling the temperature of the substrate being treated, but do not refer to the method(s) of control, or the spatial area under control, or the temporal (time) temperature profile of the substrate before, during, or after the substrate passes through the reaction zone during the process scan. While increased surface temperature in the reaction zone is generally desirable to increase chemical reaction rates, it is sometimes desirable to maintain the average temperature of the substrate at as low a temperature as possible, due to thermal sensitivities of that substrate. Also, if the surface treated with atmospheric plasma is still at an elevated temperature when it comes in contact with room air after the atmospheric plasma treatment, undesirable reactions with air may occur. Current state-of-the-art in atmospheric plasma processing offers only temperature rise by external substrate heating; or by the temperature of the gas emitted from the atmospheric plasma aperture. No provisions for active, integrated spatial and/or temporal thermal control of the substrate and plasma head are disclosed in the literature.

### Integrated Thermal Management for Surface Treatment with Atmospheric Plasma

The present application teaches, among other innovations, integrated process methods and hardware implementations, incorporated into atmospheric plasma processing systems which utilize multiple heating and cooling techniques to allow maximum flexibility in the control of substrate temperature, plasma gas temperature, and plasma head temperature, both spatially and temporally. Whole-substrate heating and cooling are combined with thermal control zones just adjacent to the plasma aperture, control of the plasma gas temperature through plasma parameters, control of plasma head body temperature, and pre-heating of gasses prior to entry to the plasma head.

### BRIEF DESCRIPTION OF THE DRAWINGS

The disclosed inventions will be described with reference to the accompanying drawings, which show important sample embodiments and which are incorporated in the specification hereof by reference, wherein:

FIG. 1 shows various temperature control zones within an exemplary atmospheric plasma processing system.

FIG. 2 schematically shows the main components of an exemplary atmospheric plasma processing system.

FIG. 3 shows elements of a Surface Pre-Conditioning Zone in one sample embodiment.

FIG. 4 shows elements of a Surface Post-conditioning Zone in one sample embodiment.

FIG. 5 shows elements of a Process Reaction Zone in one sample embodiment.

### DETAILED DESCRIPTION OF SAMPLE EMBODIMENTS

The numerous innovative teachings of the present application will be described with particular reference to presently preferred embodiments (by way of example, and not of limitation). The present application describes several inventions, and none of the statements below should be taken as limiting the claims generally.

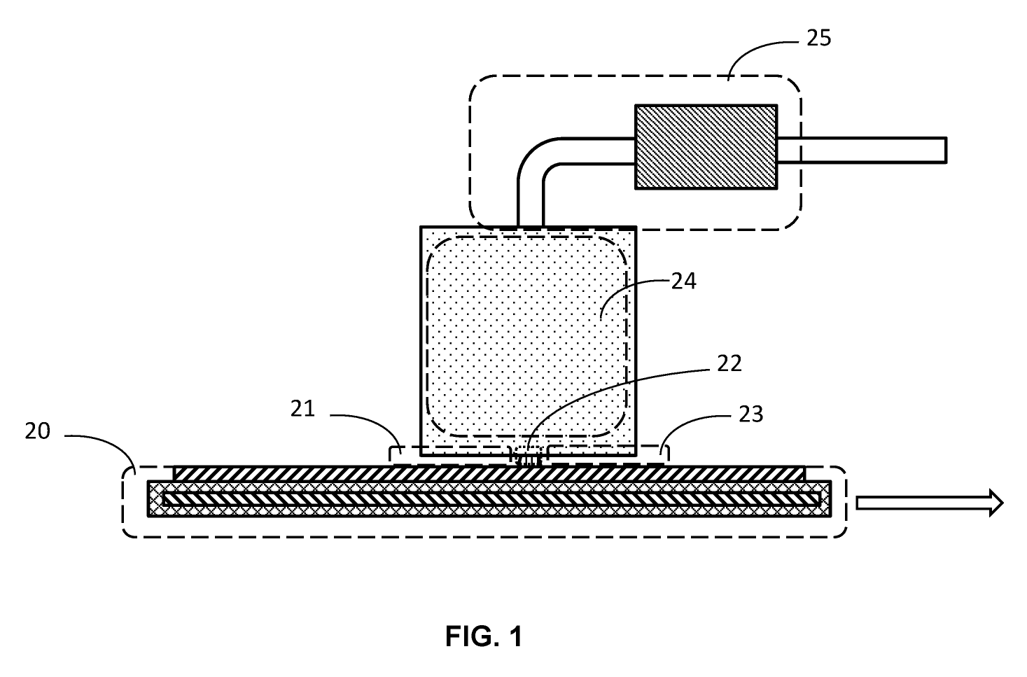

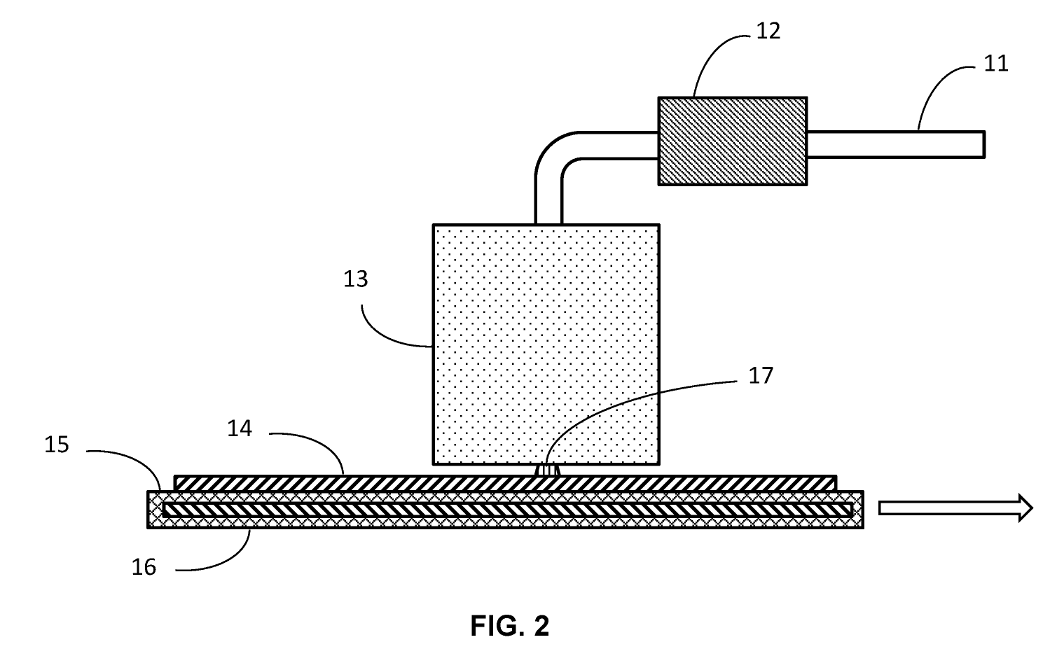

The present inventions relate generally to systems and methods for integrated thermal management of substrates being treated with atmospheric plasma. This is accomplished by systematically controlling the temperatures of critical zones within the atmospheric plasma processing system components. The system components, as shown in FIG. 2, consist of process gas supply line 11, inlet gas pre-heater 12, atmospheric plasma head 13, substrate under treatment 14, substrate scanning stage 15, and scanning stage heater/cooler element 16, and plasma processing zone 17. FIG. 1 shows the relative locations of the independent temperature control zones, which are: whole-substrate heating and cooling zone 20, surface pre-conditioning zone 21, process reaction zone 22, surface post-conditioning zone 23, plasma head body zone 24, and gas pre-heat zone 25.

### Whole-Substrate Heating and Cooling

For certain processing applications, for example photoresist removal or organic residue removal, it is desirable for the entire substrate to be pre-heated to accelerate surface chemistry reactions. In some sample embodiments, this is accomplished with the use of heating element(s) attached to, or embedded into, the substrate chuck. However, in some applications, it is not possible or desirable to heat the entire substrate to the ultimate temperature needed to achieve the required removal rate. In this case, additional heat can be added to the substrate surface in pre-conditioning zone 21, so that the surface to be immediately processed reaches a higher temperature than the bulk of the substrate.

Conversely, some other applications of atmospheric plasma, such as oxide removal from metals, benefit from a cool substrate so that employing a cooling element in substrate chuck 20 will allow the freshly reduced surface to be cooled and therefore less reactive when it becomes exposed to room air after atmospheric plasma treatment. In this case, integrating whole-substrate cooling 20 with post-conditioning zone 23 cooling provides a process advantage by providing double-cooling locally to the surface previously heated by exposure to the atmospheric plasma process reaction zone 22. The present inventions emphasize the synergistic benefits of multiple heating or cooling zones.

### Surface Pre-Conditioning Zone 21:

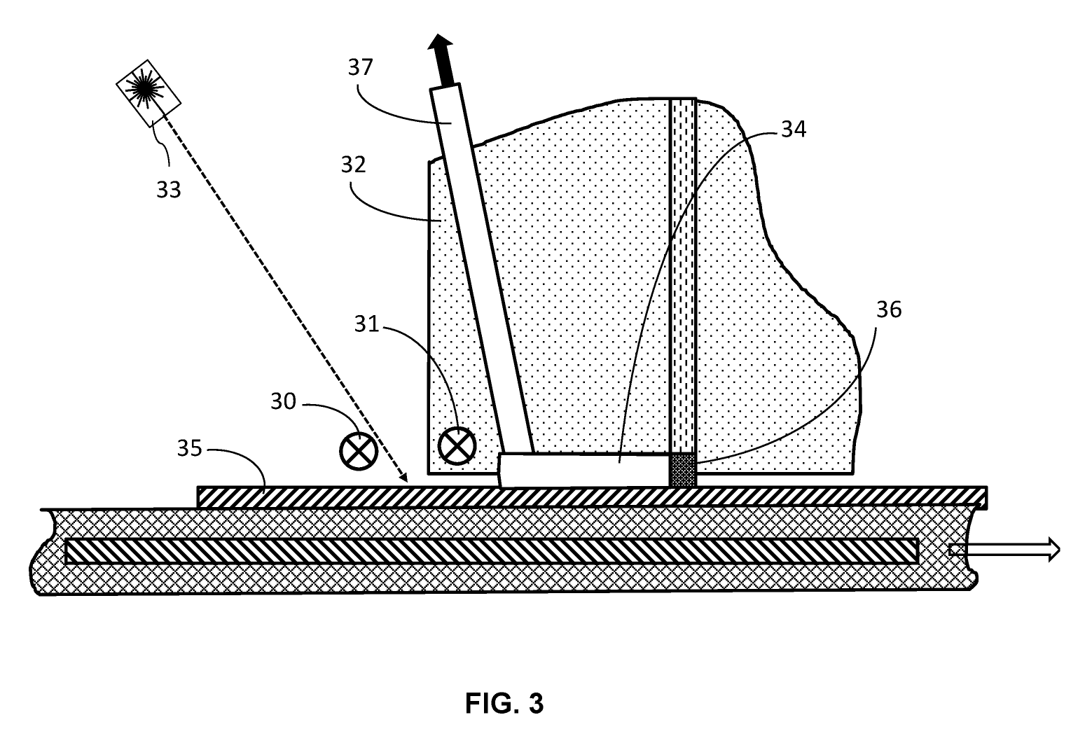

As previously mentioned, additional heating immediately prior to the substrate being scanned under the plasma reaction zone can provide process rate benefit (e.g. photoresist removal process). Referring to FIG. 3, this additional heating can come from a heating element located near (e.g. at point 30) or inside (e.g. at point 31) the leading edge of plasma head 32, or from external laser 33, or by channeling heated process gasses (via e.g. region 34) from reaction zone 36 over the surface of arriving substrate 35 to create additional heat transfer from the heated process gas to the substrate. The channeled gas is exhausted through controlled vacuum exhaust 37. Any or all of these methods could be used to heat the substrate surface just prior to translation of the surface through process reaction zone 36.

Alternatively, for some atmospheric plasma processes (e.g. surface activation) it may be desirable to utilize the Pre-Conditioning Zone to cool the substrate. In this case, the pre-conditioning zone would be configured with gas cooling channels, as described in the next section.

In either the heating or cooling case, the Surface Pre-Conditioning Zone can also contain process gas exhaust port 37 for collection of the process gasses rather than allowing them to flow out over the surface of the substrate and into the general atmosphere.

### Surface Post-Conditioning Zone 23:

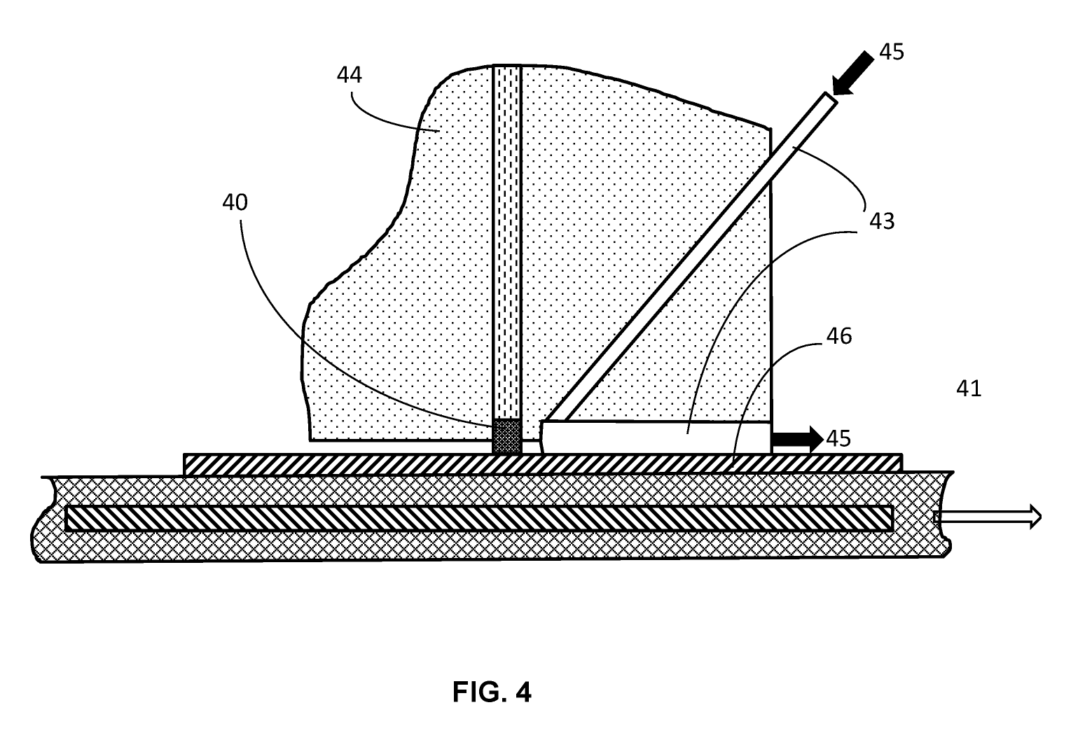

FIG. 4 shows one sample embodiment of the Surface Post-Conditioning Zone. For processes such as removal of oxidation from metals, it is important that the surface be cooled after leaving process reaction zone 40 and before exposure to room air 41. This will retard re-oxidation and extend the life of the passivation induced by the atmospheric plasma passivation process. To accomplish this cooling process, gas channels 42 are formed in the base surface of plasma head 44 such that gas flow 45 provides surface cooling and also a non-reactive environment so that substrate surface 46 can cool before exposure to room air.

Alternatively, for other atmospheric plasma processes (e.g. photoresist removal), the Post-Conditioning Zone can be configured as a heating zone, as previously described in reference to FIG. 3.

In either the heating or cooling case, the Surface Pre-Conditioning Zone or Surface Post-conditioning Zone can also contain a gas exhaust port (e.g. element 37 of FIG. 3) for collection of the process or cooling gasses rather than allowing them to flow out over the surface of the substrate and into the general atmosphere.

The integration of a Post-Conditioning Zone is synergistic with the Whole-Substrate Temperature Control and Pre-conditioning Zone, and represents one point of novelty of the present inventions.

### Process Reaction Zone 22

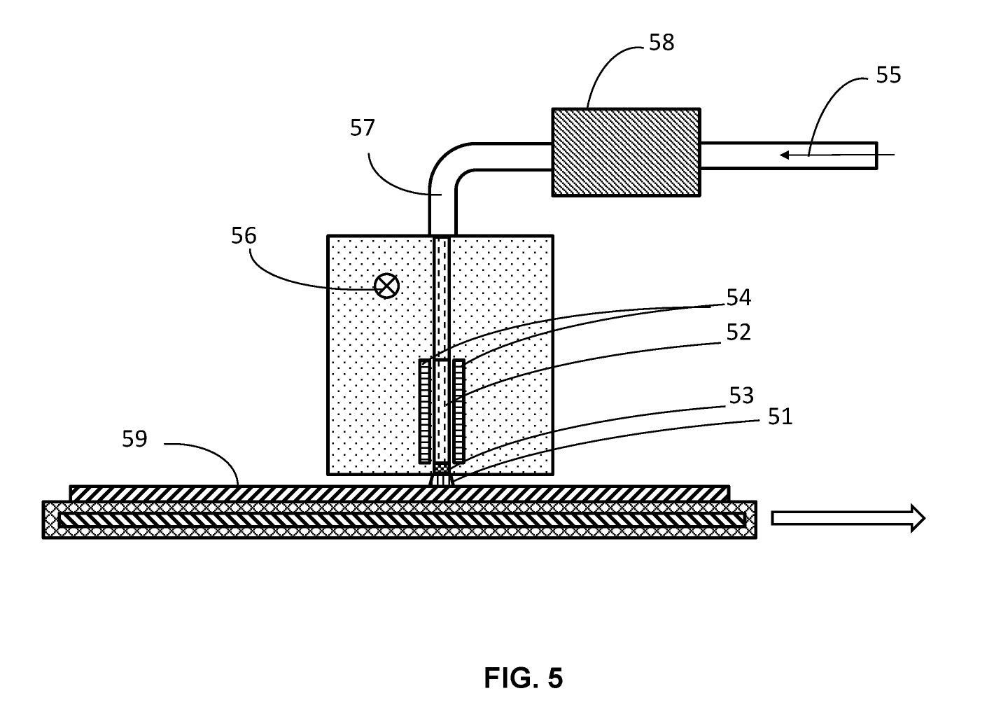

FIG. 5 shows details of one sample embodiment of thermal control in the Process Reaction Zone 51 where it contacts substrate 59. The temperature of the gas in this zone also has a profound effect on surface chemistry rate control. This is primarily affected by the temperature of the gas exiting plasma zone 52 and subsequently plasma aperture 53. Exiting gas temperature is a function of several plasma parameters, including without limitation RF power on electrodes 54, total gas flow, gas selection, flow ratios of multiple gasses being flowed simultaneously through region 55, temperature of the internal surfaces of the plasma head as controlled by separate heater 56 which are in contact with the flowing gas, and initial temperature of gas 57 as controlled by upstream gas heater 58.

For some Atmospheric Plasma process applications, such as photoresist removal or organic contamination removal, higher temperatures in the Process Reaction Zone are desirable. In this case, increasing RF power, decreasing total gas flow, adding Nitrogen or Argon, or Oxygen+Hydrogen into the gas composition, pre-heating of the gasses before they enter the plasma zone, and additional heating of the plasma head internal surfaces will all serve to increase the gas temperature in the Process Reaction Zone.

Conversely, if a low-temperature surface modification process is desirable, such as treating thermally delicate substrates, or creating a passivation monolayer on the treated surface, or activating photoresist, one can decrease RF power, increase total gas flows, reduce or eliminate high-thermal gasses, cool the plasma head internal surfaces, and reduce or eliminate gas pre-heating.

Once again, the integration of temperature control in the Process Reaction Zone with that in the Whole-Substrate Temperature Zone, Pre-conditioning Zone, and Post-Conditioning Zone provide novel methods of synergistic control over a variety of Atmospheric Plasma processes, as highlighted in the sample embodiments disclosed below.

Any inclusive, or exclusive combination of the above-listed zone temperature control schemes should also be considered novel and encompassed by the present inventions.

### Organic Film Removal

Removal of photoresist (or other organic film) is generally aided by high surface temperature and high density of active species in the process reaction zone. Therefore, for this process, it is beneficial to apply as much heat as possible in the following temperature control zones. Whole-substrate heating is preferably operated at 175° C. or above. Pre-conditioning Zone preferably applies additional heating from heating elements, laser, or channeled process gas outflow from the Process Reaction Zone. The temperature of gasses in the Process Reaction Zone is preferably maximized, by e.g. increasing gas preheating and/or plasma excitation power, selecting high-thermal gasses, and providing high gas flow. The Post-conditioning Zone in such an embodiment preferably includes a “dam” to minimize process gasses from flowing into this zone, thus forcing the process gasses in the Process Reaction Zone to flow in the direction of the pre-conditioning Zone. The following parameters represent one combination (of many) which would be beneficial to photoresist or organic film removal:
Whole-substrate heating at 200° C.
External pre-heating element operating at 300° C.,
Process gas being drawn into the Pre-conditioning Zone by an exhaust port located near the leading edge of the Pre-conditioning Zone,
Convection heating of the gas supply using a heated tube at 100-300° C.,
Plasma RF power at 100-200 Watts per inch of linear aperture,
Helium flow of 5-20 Standard Liters Per Minute (SLPM) per inch of linear aperture,
Oxygen flow of 0.02-0.2 SLPM per inch of linear aperture,
Hydrogen flow at 10-50% of Oxygen flow.
Substrate translation rate beneath the aperture of 0.1-10.0 mm/sec.

It is recognized that variations in heating from the individual zones may be desirable to accommodate varying film and substrate combinations and removal rates.

### De-oxidation and Passivation of Metallic Surfaces:

Reduction of metal oxides is aided by high surface temperature and high density of active species in the process reaction zone. However, re-oxidation of the metal surface can occur if the surface is too hot when it gets re-exposed to room air after the reduction/passivation process. Therefore, for this application, it is beneficial to apply a combination of heating and cooling in the following temperature control zones. Whole-substrate cooling is preferably operated at 30° C. or below. Pre-conditioning Zone preferably applies heating from heating elements, laser, or channeled process gas outflow from the Process Reaction Zone. The temperature of the gasses in the Process Reaction Zone is preferably maximized, by e.g. increasing Gas Preheating, increasing Plasma excitation power, selecting high-thermal gasses, and providing high gas flow. The Post-conditioning Zone preferably includes a “dam” to minimize process gasses from flowing into this zone, as previously described, but also a cooling zone created by the flow of cool non-reactive gas over the surface to reduce surface temperature before it exits the protective gas blanket into room air.

The following exemplary parameters represent one combination (of many) which would be beneficial to de-oxidation and passivation of metal surfaces:
Whole-substrate cooling at below 30° C. (but above dew point for the ambient atmosphere conditions)
External pre-heating element operating at 150° C.,
Process gas being drawn into the Pre-conditioning Zone by an exhaust port located near the leading edge of the Pre-conditioning Zone,
Convection heating of the gas supply using a heated tube at 100° C.,
Plasma RF power at 120 Watts per inch of linear aperture,
Helium flow of 10 Standard Liters Per Minute (SLPM) per inch of linear aperture,
Nitrogen flow of 0.1 SLPM per inch of linear aperture,
Hydrogen flow of 0.2 SLPM per inch of linear aperture.
Substrate translation rate beneath the aperture of 0.1 to 5.0 mm/sec.

It is recognized that variations in heating and cooling from the individual zones may be desirable to accommodate varying metal oxide and substrate combinations and removal rates.

### Photoresist Descum and Surface Activation for Plating:

This process requires that the surface be maintained at relatively cool temperatures so as to not disturb the photoresist pattern dimensions, and to not re-oxidize the surface of the exposed plating base metal after processing. Therefore, it is beneficial to apply a combination of cooling and moderate heating in the following temperature control zones. Whole-substrate cooling is preferably operated at 30° C. or below. Pre-conditioning Zone preferably applies heating only from channeled process gas outflow from the Process Reaction Zone. The temperature of the gasses in the Process Reaction Zone is preferably moderated by eliminating Gas Preheating, decreasing plasma excitation power, selecting low-thermal gasses, and providing low gas flow. The Post-conditioning Zone preferably includes a “dam” to minimize process gasses flowing into this zone, as previously described, and also a cooling zone created by the flow of cool non-reactive gas over the surface to reduce surface temperature before it exits the protective gas blanket into room air. The following exemplary parameters represent one sample combination (of many) which would be beneficial to photoresist descum and surface activation for plating:
Whole-substrate cooling at below 30° C. (but above dew point for the ambient atmosphere conditions),
External pre-heating element inactive,
Process gas being drawn into the Pre-conditioning Zone by an exhaust port located near the leading edge of the Pre-conditioning Zone,
No convection heating of the gas supply,
Plasma RF power at 80 Watts per inch of linear aperture,
Helium flow of 10 Standard Liters Per Minute (SLPM) per inch of linear aperture,
Nitrogen flow of 0.1 SLPM per inch of linear aperture,
Hydrogen flow of 0.2 SLPM per inch of linear aperture.
Substrate translation rate beneath the aperture of 0.1 to 5.0 mm/sec.

It is recognized that variations in heating and cooling from the individual zones may be desirable to accommodate varying photoresist, metal plating base, and substrate combinations.

### Surface Activation for Direct Bonding:

This application requires that the surface remain at or near room temperature. Therefore, in some sample embodiments, it is beneficial to apply a combination of cooling and minimum heating in the following temperature control zones. Whole-substrate cooling is preferably operated at room temperature. Pre-conditioning Zone preferably applies heating only from channeled process gas outflow from the Process Reaction Zone, but this heating is preferably minimized by increasing the exhaust flow rate. The temperature of the gasses in the Process Reaction Zone is preferably minimized by eliminating Gas Preheating, decreasing plasma excitation power, selecting low-thermal gasses, and providing low gas flow. The Post-conditioning Zone preferably includes a “dam” to minimize process gasses from flowing into this zone, as previously described, and also a cooling zone created by the flow of cool non-reactive gas over the surface to reduce surface temperature before it exits the protective gas blanket into room air. The following parameters represent one exemplary combination (of many) which would be beneficial to photoresist descum and surface activation for plating:
Whole-substrate cooling at room temperature,
External pre-heating element inactive,
Process gas being drawn into the Pre-conditioning Zone by an exhaust port located near the leading edge of the Pre-conditioning Zone, using an exhaust rate of greater than 100 LPM.
No convection heating of the gas supply,
Plasma RF power at 80 Watts per inch of linear aperture,
Helium flow of 10 Standard Liters Per Minute (SLPM) per inch of linear aperture,
Nitrogen flow (or Oxygen flow) of 0.1 SLPM per inch of linear aperture,
Substrate translation rate beneath the aperture of 2.0 to 10.0 mm/sec.

It is recognized that variations in heating and cooling from the individual zones may be desirable to accommodate varying photoresist, metal plating base, and substrate combinations.

The head-mounted pre-heating element (5), plasma power and gas density (3), and metered exhaust are all instantaneously variable/controllable (say, with time constants of a few seconds). This implies control based on the process zone's location on the wafer.

For instance, when scanning across the substrate entry and exit edges (boundary conditions), the thermal absorptivity of the substrate/chuck boundary (edge) is different than the substrate interior. Namely, at the edge, there are two different materials, each a different distance from the head. The effect of this discontinuity is smoothed e.g. by varying the energy output of the pre-heater (5) owing to the knowledge of the substrate edge-location within the scan.

Similarly, the substrate/chuck boundary, a step, is aerodynamically different than the substrate interior. The ability to control plasma gas flow to compensate for the edge-step effects on process gas-flow and exhaust metering are in play.

This shows the advantages of thermal and exhaust control from the head rather than substrate-wide.

### Advantages

The disclosed innovations, in various embodiments, provide one or more of at least the following advantages. However, not all of these advantages result from every one of the innovations disclosed, and this list of advantages does not limit the various claimed inventions.
Increased throughput due to thermally enhanced chemical reaction rates;
Increased throughput by enabling higher plasma power without thermal re-oxidation;
Improved passivation effectiveness;
Improved control over substrate thermal budget by localized transient heating and/or cooling only in the immediate process area of the substrate.

According to some but not necessarily all embodiments, there is provided: Methods and systems for thermal management methods to control the rates of chemical reaction at the surface of a substrate being treated by atmospheric plasma. Integrated thermal management includes static heating and cooling of the plasma head and the substrate, as well as dynamic heating and cooling of the substrate surface, before and after the substrate passes the linear aperture of the atmospheric plasma head.

According to some but not necessarily all embodiments, there is provided: A method of treating surfaces, comprising: flowing a process gas stream, at approximately atmospheric pressure, through a plasma head and thence out an aperture to directly impinge on a surface being treated, while maintaining a glow discharge plasma inside the plasma head, and while also moving the surface being treated and/or the plasma head with respect to each other; and passing the process gas stream, downstream of the aperture, through an open channel in the surface of the plasma head, and thence into an exhaust manifold; wherein the open channel faces the surface being treated.

According to some but not necessarily all embodiments, there is provided: A method of treating surfaces, comprising: flowing a process gas stream, at atmospheric pressure, through a plasma head and thence out an aperture to directly impinge on a surface being treated, while maintaining a glow discharge plasma inside the plasma head, and while also moving the surface being treated and/or the plasma head with respect to each other; and passing the process gas stream through an open channel in the surface of the plasma head, and thence into an exhaust manifold, and metering the flow through the exhaust manifold to control the dwell time of the gas flow in contact with the surface being treated; wherein the open channel faces the surface being treated.

According to some but not necessarily all embodiments, there is provided: A method of treating surfaces, comprising: flowing a process gas stream, at atmospheric pressure, through a plasma head and thence out an aperture to directly impinge on a surface being treated, while maintaining a glow discharge plasma inside the plasma head, while controlling the temperature of the plasma head and/or the process gas flow using at least one heater, and while also moving the surface being treated and/or the plasma head with respect to each other; and passing the process gas stream through an open channel in the surface of the plasma head, and thence into an exhaust manifold within the plasma head, and metering the flow through the exhaust manifold to control the dwell time of the gas flow in contact with the surface being treated; wherein the open channel faces the surface being treated.

According to some but not necessarily all embodiments, there is provided: A method of treating surfaces, comprising: flowing a process gas stream, at approximately atmospheric pressure, through a plasma head and thence out an aperture to directly impinge on a surface being treated, while maintaining a glow discharge plasma inside the plasma head, and while also moving the surface being treated and/or the plasma head with respect to each other; wherein a radiant heater is mounted on the plasma head, and heats portions of the surface being treated just before contact with the process gas flow.

According to some but not necessarily all embodiments, there is provided: A method of treating surfaces, comprising: flowing a process gas stream, at atmospheric pressure, through a plasma head and thence out an aperture to directly impinge on a surface being treated, while maintaining a glow discharge plasma inside the plasma head, while also moving the surface being treated and/or the plasma head with respect to each other; and passing the process gas stream through an open channel in the surface of the plasma head, and thence into an exhaust manifold within the plasma head; wherein the open channel faces the surface being treated; and flowing a coolant gas onto the surface being treated, to impinge on portions of the surface which have already been exposed to the process gas stream from the aperture.

According to some but not necessarily all embodiments, there is provided: A method of treating surfaces, comprising: flowing a process gas stream, at atmospheric pressure, through a plasma head and thence out an aperture to directly impinge on a surface being treated, while maintaining a glow discharge plasma inside the plasma head, while controlling the temperature of the plasma head and/or the process gas flow using at least one heater, and while also moving the surface being treated and/or the plasma head with respect to each other; passing the process gas stream through an open channel in the surface of the plasma head, and thence into an exhaust manifold within the plasma head; wherein the open channel faces the surface being treated; and flowing a coolant gas onto the surface being treated, to impinge on portions of the surface which have already been exposed to the process gas stream from the aperture.

According to some but not necessarily all embodiments, there is provided: A system for treating surfaces at approximately atmospheric pressure, comprising: a plasma head which is connected to pass a process gas stream through a glow discharge and thence out an aperture to directly impinge on a surface being treated; means for translating the plasma head and/or the surface being treated with respect to each other, so that discharge through the aperture can be scanned over the surface being treated; an exhaust manifold connected to the aperture through an open channel in the surface of the plasma head facing the surface being treated.

According to some but not necessarily all embodiments, there is provided: A system for treating surfaces at approximately atmospheric pressure, comprising: a plasma head which is connected to pass a process gas stream through a glow discharge and thence out an aperture and into an open channel, facing the surface being treated, to directly impinge on a surface being treated; and means for translating the plasma head and/or the surface being treated with respect to each other, so that discharge through the aperture can be scanned over the surface being treated; wherein the plasma head includes an exhaust manifold which receives gas flow from the open channel; and further comprising a metering valve, interposed in the exhaust manifold, which controls the dwell time of the gas flow in contact with the surface being treated.

According to some but not necessarily all embodiments, there is provided: A system for treating surfaces at approximately atmospheric pressure, comprising: a plasma head which is connected to pass a process gas stream through a glow discharge and thence out an aperture to directly impinge on a surface being treated; and means for translating the plasma head and/or the surface being treated with respect to each other, so that discharge through the aperture can be scanned over the surface being treated; at least one heater connected to the plasma head to control the temperature thereof; wherein the plasma head includes an exhaust manifold which receives gas flow from an open channel in the plasma head, facing the surface being treated, in the surface of the plasma head; and further comprising a metering valve, interposed in the exhaust manifold, which controls the dwell time of the gas flow in contact with the surface being treated.

According to some but not necessarily all embodiments, there is provided: A system for treating surfaces at approximately atmospheric pressure, comprising: a plasma head which is connected to pass a process gas stream through a glow discharge and thence out an aperture to directly impinge on a surface being treated; and means for translating the plasma head and/or the surface being treated with respect to each other, so that discharge through the aperture can be scanned over the surface being treated; wherein a radiant heater is mounted on the plasma head, and heats portions of the surface being treated just before contact with the process gas flow.

According to some but not necessarily all embodiments, there is provided: A system for treating surfaces at approximately atmospheric pressure, comprising: a plasma head which is connected to pass a process gas stream through a glow discharge and thence out an aperture to directly impinge on a surface being treated; and means for translating the plasma head and/or the surface being treated with respect to each other, so that discharge through the aperture can be scanned over the surface being treated; passing the process gas stream through an open channel in the surface of the plasma head, and thence into an exhaust manifold within the plasma head; wherein the open channel faces the surface being treated; and a coolant gas channel mounted to the plasma head, and positioned so that coolant gas flowing therethrough impinges on portions of the surface which have already been exposed to the process gas stream from the aperture.

According to some but not necessarily all embodiments, there is provided: A system for treating surfaces at approximately atmospheric pressure, comprising: a plasma head which is connected to pass a process gas stream through a glow discharge and thence out an aperture to directly impinge on a surface being treated; an exhaust manifold within the plasma head, connected to the aperture through an open channel in the surface of the plasma head; wherein the open channel faces the surface being treated; means for translating the plasma head and/or the surface being treated with respect to each other, so that discharge through the aperture can be scanned over the surface being treated; at least one heater connected to the plasma head to control the temperature thereof; a coolant gas channel mounted to the plasma head, and positioned so that coolant gas flowing therethrough impinges on portions of the surface which have already been exposed to the process gas stream from the aperture.

### Modifications and Variations

As will be recognized by those skilled in the art, the innovative concepts described in the present application can be modified and varied over a tremendous range of applications, and accordingly the scope of patented subject matter is not limited by any of the specific exemplary teachings given. It is intended to embrace all such alternatives, modifications and variations that fall within the spirit and broad scope of the appended claims.

In some embodiments, non-reactive gasses are used in the cooling zone—preferably Ar.

In some embodiments, N2 cooling gas can be used for cost savings if the treated surface is not subject to reaction with Nitrogen.

In some embodiments, a carriage moves the plasma head as required.

In some embodiments, the exhaust is an exhaust manifold located in the plasma head.

In presently-preferred embodiments, the channel is an open channel, i.e. is open to the surface being treated.

Additional general background, which helps to show variations and implementations, as well as some features which can be implemented synergistically with the inventions claimed below, may be found in the following patents and patent applications. All of these applications have at least some common ownership, copendency, and inventorship with the present application, and all of them, as well as any material directly or indirectly incorporated within them, are hereby incorporated by reference: U.S. Pat. No. 8,567,658; US 20130270329; U.S. Pat. No. 9,909,232; WO 2013/134054; WO 2016/077645; WO 2017/031258.

None of the description in the present application should be read as implying that any particular element, step, or function is an essential element which must be included in the claim scope: THE SCOPE OF PATENTED SUBJECT MATTER IS DEFINED ONLY BY THE ALLOWED CLAIMS. Moreover, none of these claims are intended to invoke paragraph six of 35 USC section 112 unless the exact words “means for” are followed by a participle.

The claims as filed are intended to be as comprehensive as possible, and NO subject matter is intentionally relinquished, dedicated, or abandoned.

1. A method of treating surfaces, comprising:
flowing a process gas stream, at approximately atmospheric pressure, through a plasma head and thence out an aperture to directly impinge on a surface being treated,
while maintaining a glow discharge plasma inside the plasma head, and
while also moving the surface being treated and/or the plasma head with respect to each other; and
passing the process gas stream, downstream of the aperture, through an open channel in the surface of the plasma head, and thence into an exhaust manifold; wherein the open channel faces the surface being treated.

2. The method of claim 1, further comprising heating the plasma head to a controlled temperature.

3. The method of claim 1, further comprising heating portions of the surface, by scanning a laser, just before they pass under the plasma head.

4. The method of claim 1, further comprising heating the plasma head to a controlled temperature.

5. The method of claim 1, further comprising uniformly heating the entire surface being treated.

6. The method of claim 1, further comprising uniformly cooling the entire surface being treated.

7. The method of claim 1, wherein the process gas stream comprises nitrogen.

8. The method of claim 1, wherein the process gas stream comprises N2 gas.

9. The method of claim 1, wherein the process gas stream comprises argon.

10. A method of treating surfaces, comprising:
flowing a process gas stream, at atmospheric pressure, through a plasma head and thence out an aperture to directly impinge on a surface being treated,
while maintaining a glow discharge plasma inside the plasma head, and
while also moving the surface being treated and/or the plasma head with respect to each other; and
passing the process gas stream through an open channel in the surface of the plasma head, and thence into an exhaust manifold, and metering the flow through the exhaust manifold to control the dwell time of the gas flow in contact with the surface being treated; wherein the open channel faces the surface being treated.

11. The method of claim 10, wherein the exhaust manifold is located within the plasma head.

12. The method of claim 10, further comprising heating the plasma head to a controlled temperature.

13. The method of claim 10, further comprising heating portions of the surface, by scanning a laser, just before they pass under the plasma head.

14. The method of claim 10, further comprising heating the plasma head to a controlled temperature.

15. The method of claim 10, further comprising uniformly heating the entire surface being treated.

16. The method of claim 10, further comprising uniformly cooling the entire surface being treated.

17. The method of claim 10, wherein the process gas stream comprises nitrogen.

18. The method of claim 10, wherein the process gas stream comprises N2 gas.

19. The method of claim 10, wherein the process gas stream comprises argon.

20. A method of treating surfaces, comprising:
flowing a process gas stream, at atmospheric pressure, through a plasma head and thence out an aperture to directly impinge on a surface being treated,
while maintaining a glow discharge plasma inside the plasma head,
while controlling the temperature of the plasma head using at least one heater, and
while also moving the surface being treated and/or the plasma head with respect to each other; and
passing the process gas stream through an open channel in the surface of the plasma head, and thence into an exhaust manifold within the plasma head, and metering the flow through the exhaust manifold to control the dwell time of the gas flow in contact with the surface being treated;
wherein the open channel faces the surface being treated.

21-109. (canceled)
